(19) United States
(12) Patent Application Publication
(10) Pub. No.: US 2019/0215000 A1
(43) Pub. Date: Jul. 11, 2019

(54) RING OSCILLATOR TOPOLOGY BASED ON RESISTOR ARRAY

(71) Applicant: QUALCOMM Incorporated, San Diego, CA (US)

(72) Inventors: Yuehai JIN, Tustin, CA (US); Xinhua CHEN, San Diego, CA (US)

(21) Appl. No.: 15/868,551

(22) Filed: Jan. 11, 2018

(51) Int. Cl. H03L 7/099; H03K 3/03; H03L 7/089

(52) U.S. Cl. CPC H03L 7/0995; H03L 7/0891; H03K 3/0315

(57) ABSTRACT

Certain aspects of the present disclosure provide methods and apparatus for generating an oscillating signal using a ring oscillator circuit. One example ring oscillator circuit generally includes one or more delay elements coupled in series, wherein an output of a last one of the delay elements is coupled to an input of an initial one of the delay elements, and a plurality of resistive elements selectively coupled to a tail node of at least a first one of the delay elements, the resistive elements being configured to coarse-tune a frequency of an oscillating signal generated by the ring oscillator circuit. For certain aspects, the ring oscillator circuit further includes a plurality of tunable capacitive elements coupled to an output node of at least a second one of the delay elements, the tunable capacitive elements being configured to fine-tune the frequency of the oscillating signal.

### TECHNICAL FIELD

Certain aspects of the present disclosure generally relate to electronic circuits and, more particularly, a ring oscillator topology based on a resistor array.

### BACKGROUND

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include a frequency synthesizer, which may be implemented with a phase-locked loop (PLL) including a voltage-controlled oscillator (VCO). The VCO may be implemented with a resonant tank circuit or a ring oscillator circuit, for example.

### SUMMARY

Certain aspects of the present disclosure generally relate to a ring oscillator circuit utilizing selective coupling of resistive elements to tune a frequency of an oscillating signal generated by the ring oscillator circuit.

Certain aspects of the present disclosure provide a ring oscillator circuit. The ring oscillator circuit generally includes one or more delay elements coupled in series, wherein an output of a last one of the delay elements is coupled to an input of an initial one of the delay elements, and a plurality of resistive elements selectively coupled to a tail node of at least a first one of the delay elements, the resistive elements for coarse-tuning a frequency of an oscillating signal generated by the ring oscillator circuit.

Certain aspects of the disclosure provide a method for generating an oscillating signal. The method generally includes operating a ring oscillator circuit comprising one or more delay elements coupled in series, wherein an output of a last one of the delay elements in the ring oscillator circuit is coupled to an input of an initial one of the delay elements in the ring oscillator circuit, and coupling a first set of a plurality of resistive elements to a tail node of at least a first one of the delay elements to set a frequency of the oscillating signal generated by the ring oscillator circuit, the resistive elements for coarse-tuning the frequency.

Certain aspects of the present disclosure provide an apparatus for controlling an oscillating signal. The apparatus generally includes means for generating the oscillating signal using one or more means for delaying a signal coupled in series, wherein an output of a last one of the means for delaying is coupled to an input of an initial one of the means for delaying; means for combining current through at least a first one of the means for delaying; and means for selectively coupling a plurality of resistive elements to the means for combining current to set a frequency of the oscillating signal, the resistive elements for coarse-tuning the frequency.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front-end, in accordance with certain aspects of the present disclosure.

FIG. 4 is a block diagram of an example phase-locked loop (PLL), in accordance with certain aspects of the present disclosure.

FIG. 5 is a schematic diagram of a conventional oscillator circuit using a current-mirror-based current tail bank for tuning a frequency of an oscillating signal generated by the oscillator circuit.

FIG. 6 is a schematic diagram of an example oscillator circuit using a resistor-based current tail bank for coarse-tuning the frequency of the oscillating signal, in accordance with certain aspects of the present disclosure.

FIG. 7 is a schematic diagram of an example oscillator circuit using variable capacitive elements for fine-tuning the frequency of the oscillating signal, in accordance with certain aspects of the present disclosure.

FIG. 8 is a block diagram of an example two-stage ring oscillator circuit with a schematic diagram for one of the two stages, in accordance with certain aspects of the present disclosure.

FIG. 9 is a flow diagram of example operations for generating an oscillating signal using a ring oscillator circuit, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structures, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

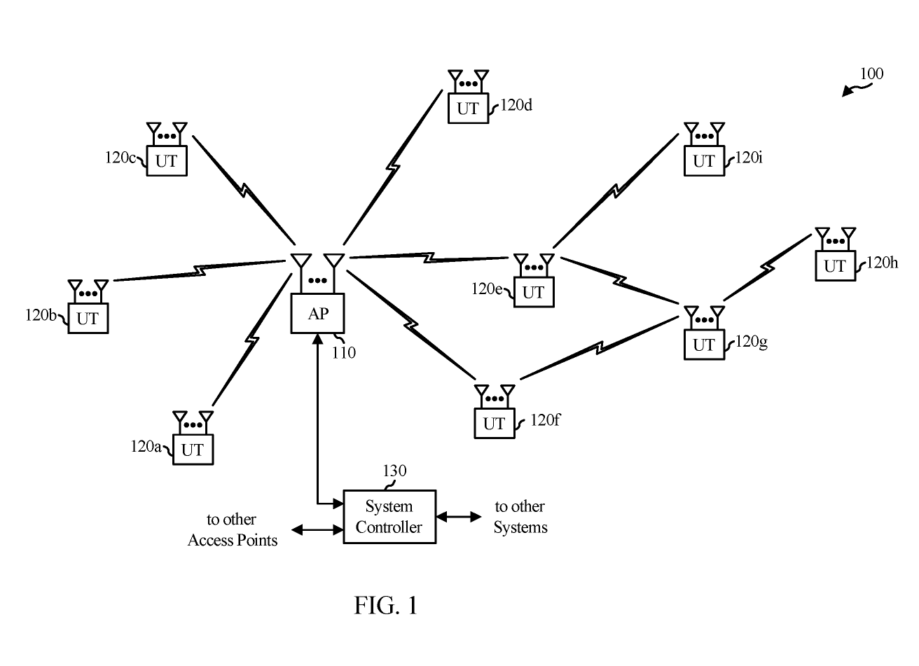

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 uses multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be supported).

In certain aspects of the present disclosure, the access point 110 and/or user terminal 120 may include at least one ring oscillator circuit, as described in more detail herein.

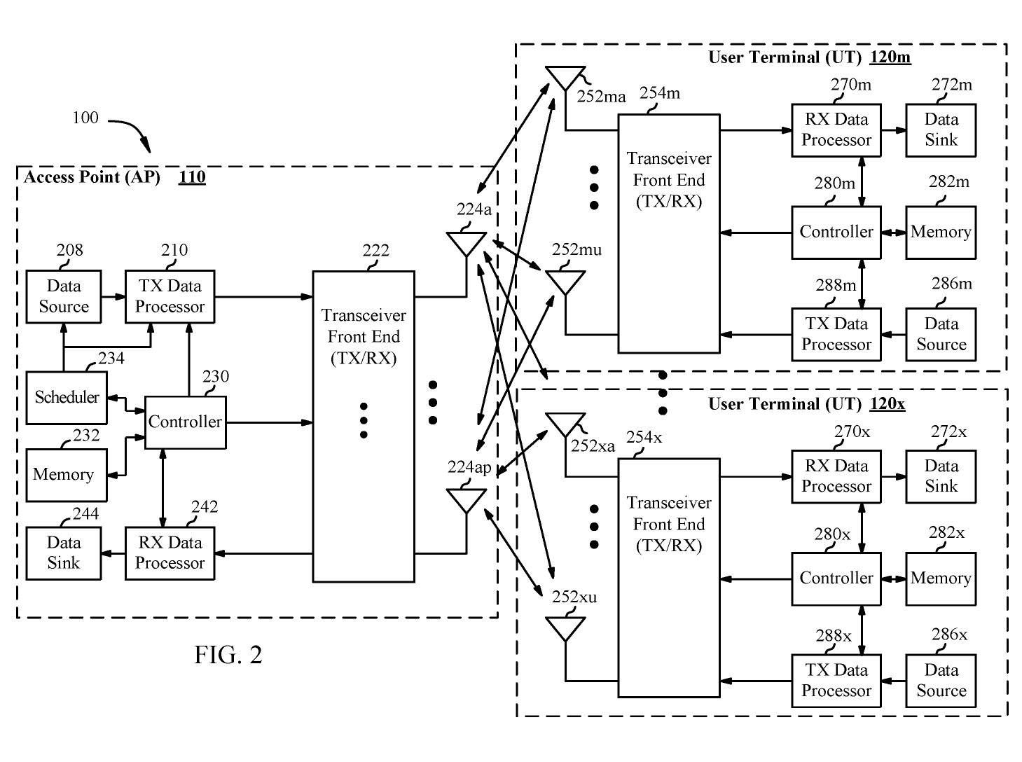

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

In certain aspects of the present disclosure, the transceiver front end (TX/RX) 222 of access point 110 and/or transceiver front end 254 of user terminal 120 may include a ring oscillator circuit, as described in more detail herein.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

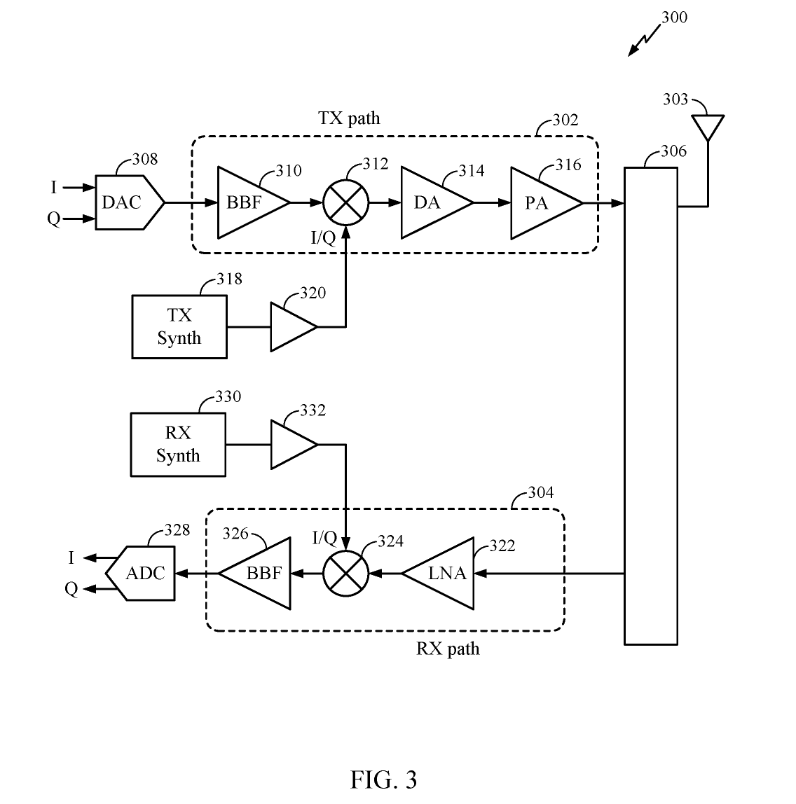

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning the LO to different frequencies typically entails using a variable-frequency oscillator, which involves compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. The VCO in the TX frequency synthesizer 318 and/or the RX frequency synthesizer 330 may be implemented, for example, by a ring oscillator, as described below.

FIGS. 1-3 provide a wireless communication system as an example application in which certain aspects of the present disclosure may be implemented to facilitate understanding. It is to be noted, however, that certain aspects provided herein can be applied to generate oscillating signals in any of various other suitable systems.

### Example Phase-Locked Loop

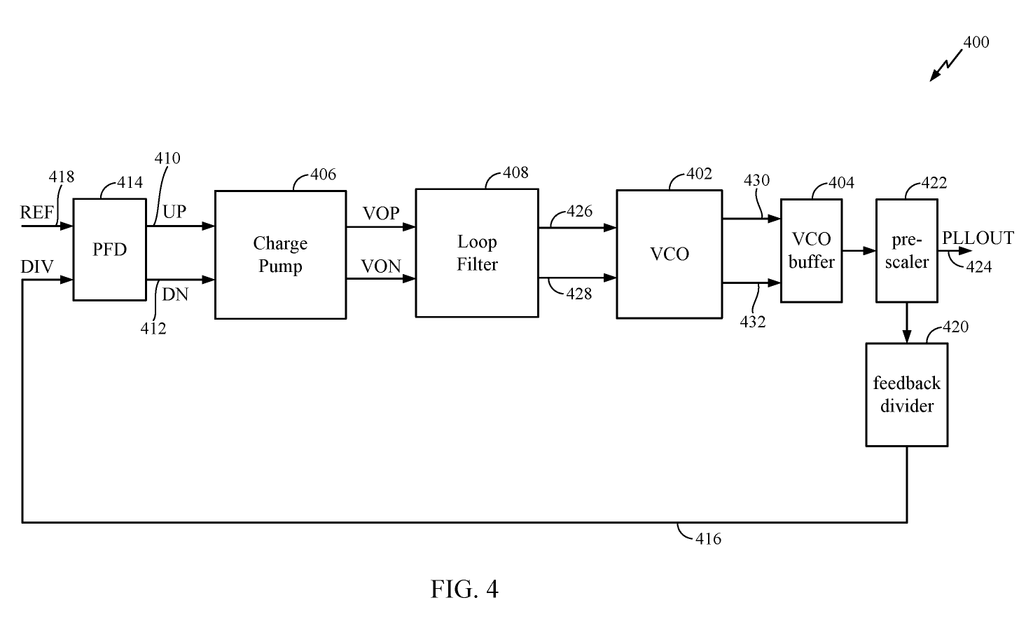

FIG. 4 is a block diagram of an example phase-locked loop (PLL) 400 comprising a VCO 402 interfaced with a VCO buffer 404, in accordance with certain aspects of the present disclosure. The PLL 400 may be utilized in a frequency synthesizer, such as the TX frequency synthesizer 318 or the RX frequency synthesizer 330 of FIG. 3.

As illustrated in FIG. 4, a charge pump 406 coupled to a low-pass loop filter 408 may provide a control voltage to the VCO 402 that determines an oscillation frequency of the VCO 402. The charge pump 406 and the VCO 402 may receive power via two power supply rails: a positive supply rail and a negative supply rail. Switches in the charge pump 406 may be controlled by up/down pulse signals 410, 412 (labeled “UP” and “DN”), and the loop filter 408 may reject the high frequency transient signals from this switching activity. These up/down pulse signals 410, 412 may be generated by a phase-frequency detector (PFD) 414, which may compare a feedback signal 416 (based on an output or processed output of the VCO 402 and labeled “DIV”) to a reference frequency signal 418 (labeled “REF”). In an aspect, as illustrated in FIG. 4, the feedback signal 416 may be generated by buffering the output of the VCO 402 with the VCO buffer 404, scaling the buffered signal in a pre-scaler 422 to generate the PLL's output signal 424 (labeled “PLLOUT”), and dividing an output of the pre-scaler 422 in a feedback divider 420. In certain aspects of the present disclosure, the charge pump 406 may be a fully differential charge pump having a switched-capacitor common-mode feedback circuit, as described below.

In some aspects of the present disclosure, as illustrated in FIG. 4, the input control voltage for the VCO 402 may be provided by the charge pump 406 and the low-pass loop filter 408 via VCO control inputs 426, 428. Circuitry of the VCO 402 may generate, at differential VCO outputs 430, 432, a periodic signal having a specific frequency (e.g., determined by a voltage at the VCO control inputs 426, 428), which may be input to the VCO buffer 404. The VCO buffer 404 may be coupled to the differential VCO outputs 430, 432 in an effort to isolate the VCO 402 from the load in the PLL 400 and other circuits receiving the PLL's output signal 424. The VCO buffer 404 may be also employed in an effort to amplify the signal swing and correct any duty cycle distortions of the differential VCO outputs 430, 432.

The VCO 402 in the PLL 400 may be implemented, for example, by a ring oscillator circuit, as described below.

### Example Ring Oscillator Circuit

Ring oscillators are an economic way to implement frequency synthesis (such as in the TX frequency synthesizer 318 or the RX frequency synthesizer 330 of FIG. 3) compared to inductor-capacitor (LC) oscillators (also referred to as resonant tank oscillators). Generally, ring oscillators are constructed from a series of logic elements (e.g., NOT gates) disposed in a ring configuration, where the output of the last element of the ring oscillator arrangement is fed back to the input of the first element. The arrangement of the ring oscillator causes the voltage in the ring oscillator to oscillate between two voltage levels. Each of the voltage levels may represent one of two binary conditions: a logical 1 or 0 value.

Oscillations in a ring oscillator may be controlled during operation thereof. Such control may change the frequency of the oscillation signal generated by the ring oscillator, allowing for circuits using such oscillators to be adaptable to changing environments or different desired frequencies. Ring oscillators, therefore, may be used as voltage-controlled oscillators (VCOs) in circuits for wireless communication devices, for example. In one example control operation, the tuning voltage to the ring oscillator arrangement may be increased. Increases of the tuning voltage, in certain aspects, cause an increase in frequency of the oscillating signal.

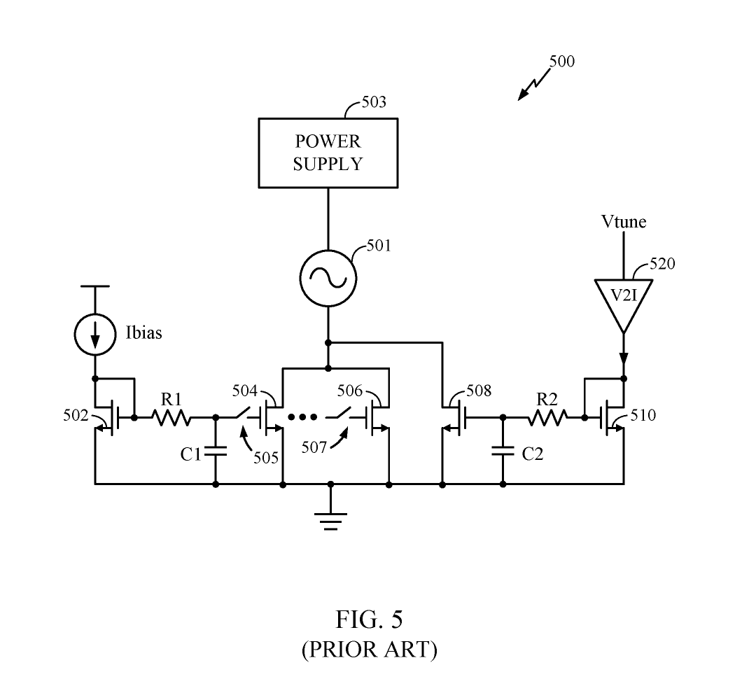

FIG. 5 is a schematic diagram of a conventional oscillator circuit 500 using a current-mirror-based current tail bank for tuning the frequency of the oscillating signal. The oscillator circuit 500 includes a ring oscillator 501, a power supply 503 for supplying power to the ring oscillator 501, and a current tail bank for tuning the frequency of the oscillating signal generated by the ring oscillator 501. The power supply 503 may be implemented by any of various suitable power circuits, such as a voltage regulator (e.g., a low dropout (LDO) regulator). The current tail bank in FIG. 5 is implemented using one or more current mirror circuits.

A first current mirror circuit includes a biasing current source (labeled “Ibias”), a transistor 502, a low-pass filter, and a plurality of transistors 504, 506, etc. The biasing current source may provide a constant bias current (e.g., 100 μA), which may be adjustable for certain aspects. Transistor 502 is implemented by an n-channel metal-oxide semiconductor (NMOS) transistor. The biasing current source is coupled to the drain of transistor 502, where the drain and the gate of transistor 502 are connected together to form the biasing branch of the first current mirror circuit. The source of transistor 502 is coupled to a reference potential node (e.g., electrical ground as shown) for the oscillator circuit 500. The low-pass filter is implemented by a first-order passive filter comprising series resistor R1 and shunt capacitor C1, as shown in FIG. 5. The input to the low-pass filter is connected to the gate of transistor 502. The output of the low-pass filter is connected to a plurality of switches 505, 507, etc. connected to the gates of transistors 504, 506, etc., respectively. The transistors 504, 506, etc. are implemented by NMOS transistors. The drains of the transistors 504, 506, etc. are connected together and to the tail of the ring oscillator 501, and the sources of the transistors 504, 506 etc. are connected to the reference potential node. Each of the transistors 504, 506, etc. may have different dimensions (e.g., width) in order to sink different currents in the output branch of the first current mirror circuit, according to the scaling between each of these transistor dimensions and the dimensions of transistor 502 in the biasing branch. In this manner, the frequency of the oscillating signal may be coarsely tuned by activating or deactivating particular switches 505, 507, etc. as desired to alter the current sunk by the selected combination of transistors 504, 506, etc. connected in parallel. Thus, the oscillator circuit 500 operates primarily as a current-controlled oscillator.

Fine-tuning of the frequency of the oscillating signal output by the ring oscillator 501 may be provided by a second current mirror circuit. As depicted in FIG. 5, this second current mirror circuit includes a voltage-to-current converter 520 (labeled “V2I”), transistors 508 and 510, and a low-pass filter. The converter 520 receives a tuning voltage (Vtune) and converts this voltage to a biasing current for the biasing branch of the second current mirror circuit. The output of the converter 520 is connected with the drain and gate of transistor 510, implemented by an NMOS transistor. The low-pass filter is a first-order passive filter implemented by series resistor R2 and shunt capacitor C2. The output of the low-pass filter is connected to the gate of transistor 508, which has a drain connected to the tail node of the ring oscillator 501 and a source connected to the reference potential node, such that transistor 508 is in parallel with transistors 504, 506, etc.

As described above, conventional ring oscillator circuits, such as the oscillator circuit 500, rely on a current tail to adjust for both coarse frequency tuning and fine frequency tuning, which results in a large resistor-capacitor (RC) filter and current mirror area and additional circuits, such as a voltage-to-current converter. Furthermore the flicker noise from the current tail cannot be filtered. Overall, conventional ring oscillator circuits have a large noise and area overhead that can make the ring oscillator circuit less attractive than a resonant tank oscillator circuit, even in non-critical applications.

Certain aspects of the present disclosure provide a ring oscillator circuit that utilizes a resistive element array for coarse frequency tuning and may also employ a variable capacitive element array for fine frequency tuning. Such a topology may eliminate the large layout area for RC filter arrangements, the current mirror(s), and the voltage-to-current converter of conventional ring oscillator circuits. This topology may also achieve better phase noise than conventional topologies while still consuming similar currents at the same frequencies as conventional topologies.

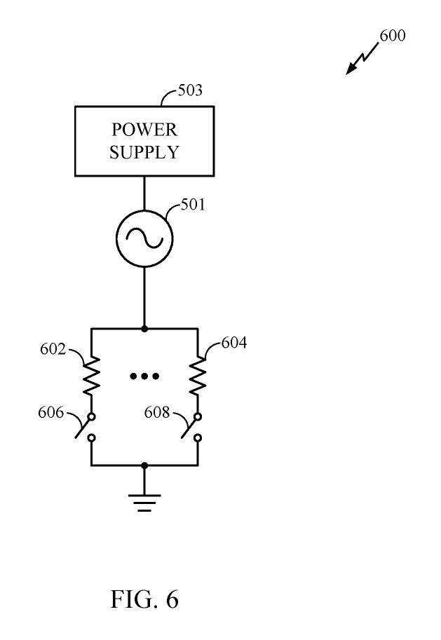

FIG. 6 is a schematic diagram of an example oscillator circuit 600 using a current tail with an array of resistive elements for coarse-tuning the frequency of the oscillating signal, in accordance with certain aspects of the present disclosure. For example, the tail node of the ring oscillator 501 may be coupled to multiple current tail branches connected in parallel. The other ends of the current tail branches may be coupled to a reference potential node (e.g., electrical ground) for the oscillator circuit 600. Each current tail branch may include a resistive element (e.g., resistors 602, 604, etc.) connected in series with a switch (e.g., switches 606, 608, etc.). Each of the resistive elements may have a constant resistance or a variable resistance. Each of the resistive elements may have a different resistance in order to sink different currents through the ring oscillator 501, based on which switches 606, 608, etc. are closed. In this manner, the frequency of the oscillating signal may be coarsely tuned by activating or deactivating particular switches 606, 608, etc. as desired to alter the current sunk by the selected combination of resistive elements connected in parallel. As a non-limiting example, the total resistance of the current tail bank may vary between 27 and 174Ω. Control signals for controlling operation of the switches 606, 608, etc. may be generated, for example, in the frequency synthesizer (e.g., TX frequency synthesizer 318 or the RX frequency synthesizer 330 of FIG. 3) with the oscillator circuit 600.

Unlike the transistors in the current tail bank of FIG. 5, resistors have significantly lower flicker noise. Therefore, filtering of the resistor-based current tail bank need not be performed, providing an area savings in contrast with the relatively large layout area of the two RC filters in FIG. 5. Furthermore, resistors are generally smaller than transistors, and thus, the thermal noise of a resistor-based current tail bank may most likely be lower than that of a transistor-based current tail bank, in addition to the area savings provided by using resistors in place of transistors. For example, the oscillator circuit 600 of FIG. 6 may have a noise improvement over conventional current-mirror-based oscillator circuits of at least 10 dBc/Hz at 1 MHz offset from a carrier frequency of 6 GHz.

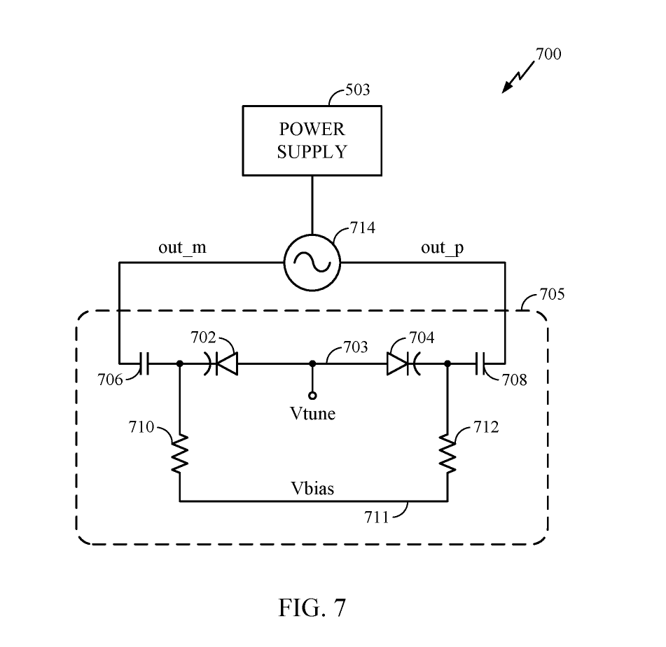

FIG. 7 is a schematic diagram of an example oscillator circuit 700 using variable capacitive elements for fine-tuning the frequency of the oscillating signal, in accordance with certain aspects of the present disclosure. The oscillator circuit 700 includes a ring oscillator 714 and a power supply 503 for supplying power to the ring oscillator 714. The ring oscillator 714 may have a tail node (not shown) for coarse-tuning of the frequency of the oscillating signal, and for certain aspects, this tail node may be coupled to the multiple current tail branches with resistive elements illustrated in FIG. 6. The differential output (out_p and out_m) of the ring oscillator 714 may be coupled to the fine-tuning circuit 705, which may include fixed capacitive elements (e.g., capacitors 706 and 708) and/or variable capacitive elements (e.g., varactors 702 and 704) connected in series as shown. The tuning voltage (Vtune) at tuning voltage node 703 may provide an analog control signal for adjusting the capacitance of the variable capacitive elements. The capacitive elements may be biased (e.g., reverse-biased) using a bias voltage (Vbias) at bias node 711 and resistive elements (e.g., resistors 710, 712) or other impedances coupled to the capacitive elements. By adjusting the capacitance values coupled to the differential output of the oscillator circuit 700, the frequency of the oscillating signal at the differential output can be fine-tuned.

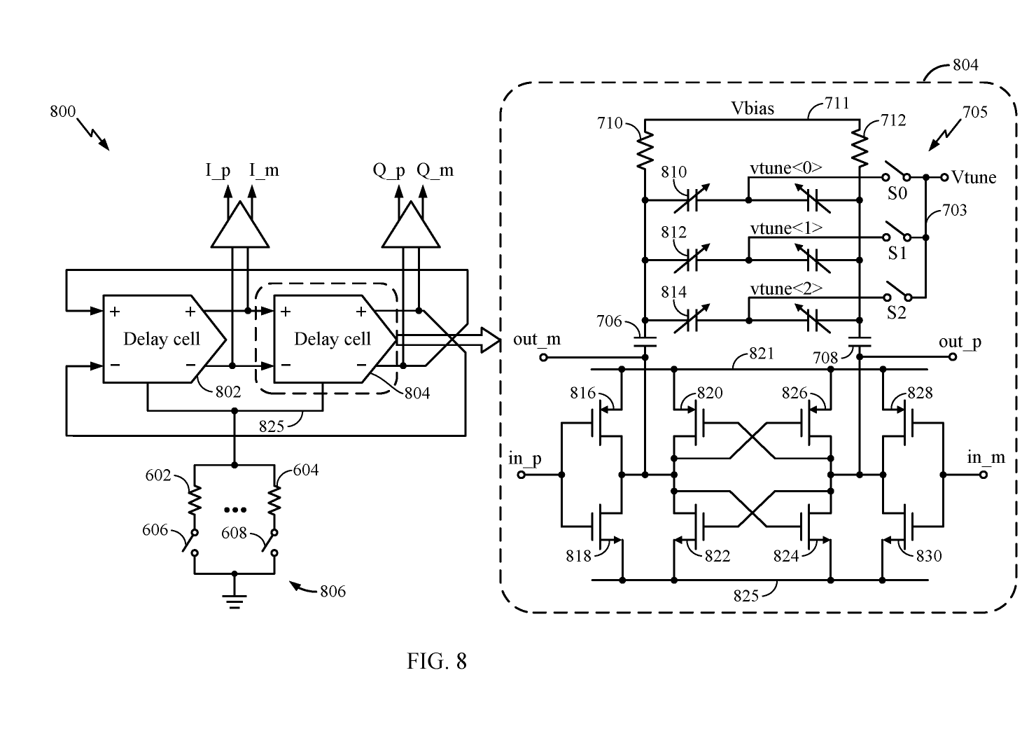

For certain aspects (as illustrated in detail in FIG. 8), the fine-tuning circuit 705 may include multiple branches where the fixed and/or variable capacitive elements have different capacitances in each branch. In this manner, different combinations of branches may be selected to fine-tune the frequency of the oscillating signal in the oscillator circuit 700.

As illustrated in FIG. 7, the fine-tuning circuit need not include a voltage-to-current converter (e.g., converter 520 in FIG. 5). The elimination of the voltage-to-current converter removes the noise and layout area of this converter from the oscillator circuit. Additionally, the oscillator circuit 700 need not include current mirror transistors (e.g., transistors 508 and 510) and the flicker noise associated therewith. Furthermore, the oscillator circuit 700 need not include a low-pass filter (e.g., R2 and C2), thereby saving the relatively large area consumed by such RC filters. The variable-capacitive-element-based fine-tuning circuit of FIG. 7 thus provides considerable space savings and reduced noise compared to much larger conventional current-mirror-based fine-tuning circuits (as shown in the circuit 500 of FIG. 5).

FIG. 8 is a block diagram of an example multi-stage ring oscillator circuit 800, in accordance with certain aspects of the present disclosure. Although only two stages are shown in the oscillator circuit 800, it is to be understood that the multi-stage oscillator circuit may include more than two stages. Each stage may include a delay cell (e.g., a first delay cell 802 or a second delay cell 804), and the stages may be coupled in series. The output of the last delay cell in the series (e.g., the second delay cell 804) may be coupled to the input of the initial delay cell in the series (e.g., the first delay cell 802) to form a ring oscillator. For differential delay cells, as shown in FIG. 8, the positive output signal from the last delay cell may be coupled to the negative input terminal of the initial delay cell, and the negative output signal from the last delay cell may be coupled to the positive input terminal of the initial delay cell. Each delay cell may comprise a logic gate with an inverted output, such as an inverter (e.g., a NOT gate).

With a two-stage ring oscillator circuit, the stages may output quadrature signals. For example, the first delay cell 802 may output a differential in-phase (I) signal (labeled as “I_p” and “I_m”), and the second delay cell 804 may output a differential quadrature (Q) signal (labeled as “Q_p” and “Q_m”), where Q_p is 90° out of phase with I_p and 180° out of phase with Q_m.

Each delay cell may include a head node 821 and a tail node 825. The head node 821 of each delay cell may be used for receiving power from a power supply (e.g., power supply 503). For certain aspects, two or more of the head nodes 821 of the different delay cells may be connected together for receiving power from the same power supply. The tail node 825 of each delay cell may be used for sinking current through the circuit elements in the delay cell, which may control the frequency of the oscillating signal generated by ring oscillator. For certain aspects, two or more of the tail nodes 825 of the different delay cells may be connected together and connected to a current tail bank 806. As described above with respect to FIG. 6, the current tail bank 806 may include multiple current tail branches connected in parallel. The other ends of the current tail branches may be coupled to a reference potential node (e.g., electrical ground) for the oscillator circuit 800. Each current tail branch may include a resistive element (e.g., resistors 602, 604, etc.) connected in series with a switch (e.g., switches 606, 608, etc.). In this manner, as described above, coarse tuning of the frequency of the oscillating signal(s) output by the ring oscillator formed by the delay cells (e.g., the first and second delay cells 802, 804) may be accomplished. As a non-limiting example, the total resistance of the current tail bank 806 may vary between 21 and 527Ω.

FIG. 8 also illustrates example circuit components for a differential delay cell, such as the second delay cell 804. The differential delay cell may be implemented with complementary metal-oxide semiconductor (CMOS) logic, for example. The CMOS logic may include PMOS transistors 816, 820, 826, and 828 and corresponding NMOS transistors 818, 822, 824, and 830. The transistors may be arranged between the head node 821 and the tail node 825 to form multiple CMOS inverter stages, as depicted, where the differential input signal (labeled “in_p” and “in_m”) is inverted to form the differential output signal (labeled “out_p” and “out_m”).

Fine-tuning of the frequency of the oscillating signal for the multi-stage ring oscillator circuit 800 may be accomplished using capacitive elements. In the example of FIG. 8, a bank of multiple variable capacitive element pairs 810, 812, and 814 is AC-coupled by fixed capacitive elements (e.g., capacitors 706 and 708) to the output terminals of the differential delay cell. As described above, each of the branches with a variable capacitive element pair 810, 812, or 814 may have a different nominal capacitance. For example, the variable capacitive elements in each branch may have nominal capacitance values of 1.5 fF, 3 fF, and 6 fF. Each of the variable capacitive element pairs 810, 812, and 814 may be implemented by a pair of varactors, for example, such as the varactors 702 and 704 in FIG. 7. For other aspects, each of the variable capacitive element pairs 810, 812, and 814 may be implemented by a combination of fixed and variable capacitive elements connected in series and/or in parallel. Although three variable capacitive element pairs 810, 812, and 814 are illustrated in FIG. 8, it is to be understood that the delay cell may be implemented with more or less than three variable capacitive element pairs. The tuning voltage (Vtune) may be selectively coupled to each branch of the capacitive bank via a switch (e.g., switches S0, 51, and S2). In this manner, the tuning voltage may be applied to any combination of tuning voltage signal nodes (labeled “vtune<0>,” “vtune<1>,” and “vtune<2>”) to fine-tune the frequency of the oscillating signal, according to the tuning voltage. For certain aspects, only one of the delay cells may include a bank of multiple variable capacitive element pairs, while in other aspects, multiple delay cells in the multi-stage circuit may each include a bank of multiple variable capacitive element pairs for fine-tuning the frequency of the oscillating signal.

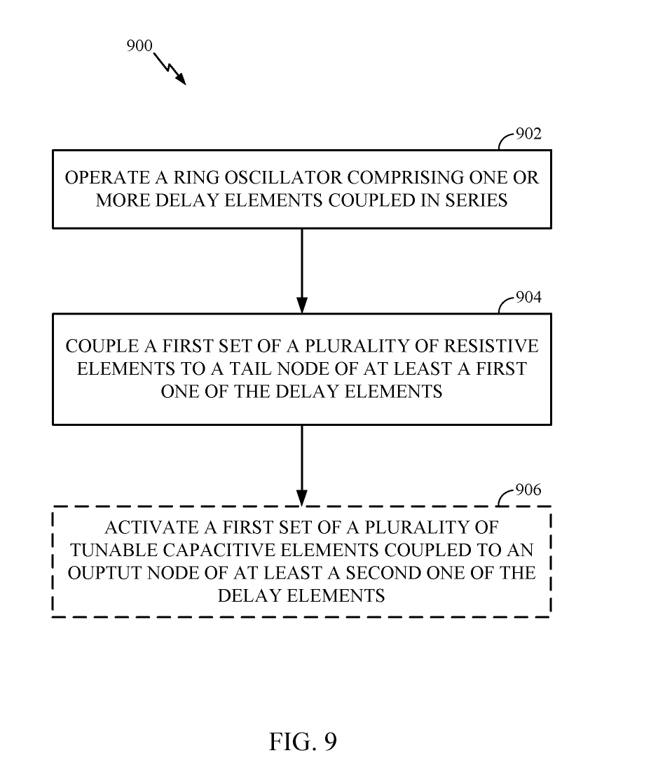

FIG. 9 is a flow diagram of example operations 900 for generating an oscillating signal, in accordance with certain aspects of the present disclosure. The operations 900 may be performed by a ring oscillator circuit, such as the oscillator circuit 600 of FIG. 6 or the multi-stage ring oscillator circuit 800 of FIG. 8.

The operations 900 may begin, at block 902, by operating a ring oscillator circuit comprising one or more delay elements (e.g., delay cells 802, 804) coupled in series. An output of a last one of the delay elements (e.g., the second delay cell 804) in the ring oscillator circuit may be coupled to an input of an initial one of the delay elements (e.g., the first delay cell 802) in the ring oscillator. At block 904, a first set of a plurality of resistive elements (e.g., resistors 602, 604, etc.) may be coupled to a tail node (e.g., tail node 825) of at least a first one of the delay elements to set a frequency of the oscillating signal generated by the ring oscillator circuit. The resistive elements may be used for coarse-tuning the frequency of the oscillating signal.

According to certain aspects, the operations 900 may further entail coupling a second set of the plurality of resistive elements to the tail node to adjust the frequency of the oscillating signal. In this case, at least one of the resistive elements is different between the first and second sets of resistive elements.

According to certain aspects, the operations 900 may further involve activating a first set of a plurality of tunable capacitive elements (e.g., variable capacitive element pairs 810, 812, and/or 814) coupled to an output node (e.g., out_p or out_m) of at least a second one of the delay elements at optional block 906. The tunable capacitive elements may be used for fine-tuning the frequency of the oscillating signal. For certain aspects, the operations 900 may further include activating a second set of the plurality of tunable capacitive elements to adjust the frequency of the oscillating signal. In this case, at least one of the activated tunable capacitive element is different between the first and second sets of the plurality of tunable capacitive elements. For certain aspects, the plurality of tunable capacitive elements comprises a plurality of varactors (e.g., varactors 702 and 704). For certain aspects, the plurality of tunable capacitive elements are AC-coupled to the output node of the at least the second one of the delay elements. For certain aspects, the at least the first one of the delay elements is the same as the at least the second one of the delay elements. For certain aspects, each of the plurality of tunable capacitive elements is coupled between the output node and a different one of a plurality of tuning nodes (e.g., vtune<0>, vtune<1>, and/or vtune<2>) for tuning the capacitive elements. In this case, activating the first set of the plurality of tunable capacitive elements at optional block 906 may involve selectively closing a plurality of switches (e.g., switch S0, S1, and/or S2) according to the first set of tunable capacitive elements. Each of the switches may be coupled between one of the plurality of tuning nodes and a same tuning voltage node (e.g., tuning voltage node 703).

According to certain aspects, coupling the first set of the plurality of resistive elements to the tail node at block 902 entails selectively closing a plurality of switches (e.g., switches 606, 608, etc.) according to the first set. In this case, each of the switches may be connected in series with one of the resistive elements between the tail node and a reference potential node for the ring oscillator circuit.

According to certain aspects, the one or more delay elements include a first delay element (e.g., first delay cell 802) and a second delay element (e.g., second delay cell 804). In this case, an output of the first delay element may be coupled to an input of the second delay element. For certain aspects, the first delay element is the initial one of the delay elements. Also, an output of the second delay element may be the output of the last delay element and may be coupled to the input of the first delay element. For certain aspects, the output of the first delay element provides an in-phase (I) oscillating signal, and the output of the second delay element provides a quadrature (Q) oscillating signal.

Certain aspects of the present disclosure provide a ring oscillator circuit. The ring oscillator circuit generally includes one or more delay elements coupled in series, wherein an output of a last one of the delay elements (in the series) is coupled to an input of an initial one of the delay elements (in the series), and a plurality of resistive elements selectively coupled to a tail node of at least a first one of the delay elements, the resistive elements for coarse-tuning a frequency of an oscillating signal generated by the ring oscillator circuit.

According to certain aspects, the ring oscillator circuit may further include a plurality of tunable capacitive elements coupled to an output node of at least a second one of the delay elements. The tunable capacitive elements may be used for fine-tuning the frequency of the oscillating signal. For certain aspects, the plurality of tunable capacitive elements comprises a plurality of varactors. For certain aspects, the ring oscillator circuit further includes a capacitive element (e.g., capacitor 706 or 708) coupled between the plurality of tunable capacitive elements and the output node of the at least the second one of the delay elements. In this case, the ring oscillator circuit may also include an impedance (e.g., resistor 710 or 712) coupled between the plurality of tunable capacitive elements and a bias node (e.g., bias node 711) associated with the at least the second one of the delay elements. For certain aspects, the at least the first one of the delay elements is the same as the at least the second of the delay elements. For certain aspects, each of the plurality of tunable capacitive elements is coupled between the output node and a different one of a plurality of tuning nodes for tuning the capacitive elements. In this case, each of the plurality of tuning nodes may be selectively coupled to a same tuning voltage node.

According to certain aspects, the ring oscillator circuit may further include a plurality of switches. Each of the switches may be connected in series with one of the resistive elements between the tail node and a reference potential node for the ring oscillator circuit.

According to certain aspects, the one or more delay elements include a first delay element and a second delay element. In this case, an output of the first delay element may be coupled to an input of the second delay element. For certain aspects, the first delay element is the initial one of the delay elements. Also, an output of the second delay element may be the output of the last one of the delay element and may be coupled to the input of the first delay element. For certain aspects, the output of the first delay element provides an in-phase (I) oscillating signal, and the output of the second delay element provides a quadrature (Q) oscillating signal.

Certain aspects of the present disclosure provide a phase-locked loop (PLL) (e.g., the PLL 400). The PLL generally includes a charge pump, a loop filter having an input coupled to an output of the charge pump, and a ring oscillator circuit as described herein, wherein an output of the loop filter is a tuning voltage node (e.g., Vtune).

According to certain aspects, at least one of the delay elements includes a logical inverter. For certain aspects, the logical inverter is a CMOS inverter.

Certain aspects of the present disclosure provide a ring oscillator topology that utilizes a resistor array for coarse frequency tuning and, in some cases, may employ a varactor array for fine frequency tuning. This ring oscillator topology occupies a smaller layout area than conventional current-tail-based ring oscillator topologies and may also consume less current. Additionally, the ring oscillator topology of the present disclosure achieves superior phase noise performance compared to conventional ring oscillators.

The various operations of methods described above may be performed by any suitable means capable of performing the corresponding functions. The means may include various hardware component(s) and/or module(s), including, but not limited to one or more circuits. Generally, where there are operations illustrated in figures, those operations may have corresponding counterpart means-plus-function components with similar numbering.

For example, means for generating an oscillating signal may include a ring oscillator, such as the ring oscillator 501 illustrated in FIGS. 5-7. Means for delaying a signal may include a delay element, such as the first delay cell 802 or the second delay cell 804 depicted in FIG. 8. Means for combining current may include a summing node, such as the tail node 825 portrayed in FIG. 8. Means for selectively coupling may include one or more switches (e.g., switches 606 and 608 as shown in FIG. 6 or switches S0, S1, and S2 as shown in FIG. 8), which may be implemented with transistors, for example.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with discrete hardware components designed to perform the functions described herein.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A ring oscillator circuit comprising:
one or more delay elements coupled in series, wherein an output of a last one of the delay elements is coupled to an input of an initial one of the delay elements; and
a plurality of resistive elements selectively coupled to a tail node of at least a first one of the delay elements, the resistive elements being configured to coarse-tune a frequency of an oscillating signal generated by the ring oscillator circuit.

2. The ring oscillator circuit of claim 1, further comprising:
a plurality of tunable capacitive elements coupled to an output node of at least a second one of the delay elements, the tunable capacitive elements being configured to fine-tune the frequency of the oscillating signal.

3. The ring oscillator circuit of claim 2, wherein the plurality of tunable capacitive elements comprises a plurality of varactors.

4. The ring oscillator circuit of claim 2, further comprising:
a capacitor coupled between the plurality of tunable capacitive elements and the output node of the at least the second one of the delay elements; and
an impedance coupled between the plurality of tunable capacitive elements and a bias node associated with the at least the second one of the delay elements.

5. The ring oscillator circuit of claim 2, wherein the at least the first one of the delay elements is the same as the at least the second of the delay elements.

6. The ring oscillator circuit of claim 2, wherein each of the plurality of tunable capacitive elements is coupled between the output node and a different one of a plurality of tuning nodes for tuning the capacitive elements.

7. The ring oscillator circuit of claim 6, wherein each of the plurality of tuning nodes is selectively coupled to a same tuning voltage node.

8. A phase-locked loop comprising a charge pump, a loop filter having an input coupled to an output of the charge pump, and the ring oscillator circuit of claim 7, wherein an output of the loop filter is the tuning voltage node.

9. The ring oscillator circuit of claim 1, further comprising a plurality of switches, each of the switches connected in series with one of the resistive elements between the tail node and a reference potential node for the ring oscillator circuit.

10. The ring oscillator circuit of claim 1, wherein the one or more delay elements comprise a first delay element and a second delay element, wherein an output of the first delay element is coupled to an input of the second delay element, wherein the first delay element is the initial one of the delay elements, and wherein an output of the second delay element is the output of the last one of the delay elements and is coupled to the input of the first delay element.

11. The ring oscillator circuit of claim 10, wherein the output of the first delay element provides an in-phase oscillating signal and wherein the output of the second delay element provides a quadrature oscillating signal.

12. The ring oscillator circuit of claim 1, wherein the plurality of resistive elements is selectively coupled to tail nodes of all of the one or more delay elements of the ring oscillator circuit.

13. A method for generating an oscillating signal, comprising:
operating a ring oscillator circuit comprising one or more delay elements coupled in series, wherein an output of a last one of the delay elements in the ring oscillator circuit is coupled to an input of an initial one of the delay elements in the ring oscillator circuit; and
coupling a first set of a plurality of resistive elements to a tail node of at least a first one of the delay elements to set a frequency of the oscillating signal generated by the ring oscillator circuit, the resistive elements for coarse-tuning the frequency.

14. The method of claim 13, further comprising coupling a second set of the plurality of resistive elements to the tail node to adjust the frequency of the oscillating signal, wherein at least one of the plurality of resistive elements belongs to the first set, but not to the second set.

15. The method of claim 13, further comprising activating a first set of a plurality of tunable capacitive elements coupled to an output node of at least a second one of the delay elements, the tunable capacitive elements for fine-tuning the frequency of the oscillating signal.

16. The method of claim 15, further comprising activating a second set of the plurality of tunable capacitive elements to adjust the frequency of the oscillating signal, wherein at least one of the activated tunable capacitive elements belongs to the first set of the plurality of tunable capacitive elements, but not to the second set of the plurality of tunable capacitive elements.

17. The method of claim 15, wherein the plurality of tunable capacitive elements comprises a plurality of varactors.

18. The method of claim 15, wherein the plurality of tunable capacitive elements are AC-coupled to the output node of the at least the second one of the delay elements.

19. The method of claim 15, wherein the at least the first one of the delay elements is the same as the at least the second one of the delay elements.

20. The method of claim 15, wherein each of the plurality of tunable capacitive elements is coupled between the output node and a different one of a plurality of tuning nodes for tuning the capacitive elements.

21. The method of claim 20, wherein activating the first set of the plurality of tunable capacitive elements comprises selectively closing a plurality of switches according to the first set of tunable capacitive elements, each of the switches coupled between one of the plurality of tuning nodes and a same tuning voltage node.

22. The method of claim 13, wherein coupling the first set of the plurality of resistive elements to the tail node comprises selectively closing a plurality of switches according to the first set, each of the switches connected in series with one of the resistive elements between the tail node and a reference potential node for the ring oscillator circuit.

23. The method of claim 13, wherein the one or more delay elements comprise a first delay element and a second delay element, wherein an output of the first delay element is coupled to an input of the second delay element, wherein the first delay element is the initial one of the delay elements, and wherein an output of the second delay element is the output of the last one of the delay elements and is coupled to the input of the first delay element.

24. The method of claim 23, wherein the output of the first delay element provides an in-phase oscillating signal and wherein the output of the second delay element provides a quadrature oscillating signal.

25. An apparatus for controlling an oscillating signal, comprising:
means for generating the oscillating signal using one or more means for delaying a signal coupled in series, wherein an output of a last one of the means for delaying is coupled to an input of an initial one of the means for delaying;
means for combining current through at least a first one of the means for delaying; and
means for selectively coupling a plurality of resistive elements to the means for combining current to set a frequency of the oscillating signal, the resistive elements for coarse-tuning the frequency.

26. The apparatus of claim 25, further comprising:
a plurality of tunable capacitive elements coupled to an output node of at least a second one of the means for delaying, the tunable capacitive elements for fine-tuning the frequency of the oscillating signal.

27. The apparatus of claim 26, wherein each of the plurality of tunable capacitive elements is coupled between the output node and a different one of a plurality of tuning nodes for tuning the capacitive elements.

28. The apparatus of claim 27, further comprising means for selectively coupling each of the plurality of tuning nodes to a same tuning voltage node.

29. The apparatus of claim 25, wherein the one or more means for delaying comprise a first means for delaying and a second means for delaying, wherein an output of the first means for delaying is coupled to an input of the second means for delaying, wherein the first means for delaying is the initial one of the means for delaying, and wherein an output of the second means for delaying is the output of the last one of the means for delaying and is coupled to the input of the first means for delaying.

30. The apparatus of claim 29, wherein the output of the first means for delaying provides an in-phase oscillating signal and wherein the output of the second means for delaying provides a quadrature oscillating signal.
